(19) United States
(12) Patent Application Publication
(10) Pub. No.: US 2016/0037645 A1
(43) Pub. Date: Feb. 4, 2016

(54) EMBEDDED BOARD AND METHOD OF MANUFACTURING THE SAME

(71) Applicant: Samsung Electro-Mechanics Co., Ltd., Suwon-si (KR)

(72) Inventors: Jae Ean LEE, Suwon-Si (KR); Jee Soo MOK, Suwon-Si (KR); Young Gwan KO, Suwon-Si (KR); Kyung Hwan KO, Suwon-Si (KR); Yong Ho BAEK, Suwon-Si (KR)

(73) Assignee: Samsung Electro-Mechanics Co., Ltd., Suwon-si (KR)

(21) Appl. No.: 14/807,598

(22) Filed: Jul. 23, 2015

(30) Foreign Application Priority Data
Aug. 1, 2014 (KR) 10-2014-0099304
Nov. 20, 2014 (KR) 10-2014-0162759

(51) Int. Cl. H05K 1/18; H05K 1/02; H05K 3/46; H05K 3/30; H05K 3/40; H05K 1/11; H05K 3/24

(52) U.S. Cl. CPC H05K 1/183; H05K 1/115; H05K 1/111; H05K 1/0298; H05K 3/24; H05K 3/301; H05K 3/4007; H05K 3/4644; H05K 3/4697

(57) ABSTRACT

An embedded board and a method of manufacturing the same are provided. The embedded board includes a core substrate below which a mounting pad is formed, a first substrate formed below the core substrate and having a first cavity formed therein, and a second substrate formed below the first substrate and having a second cavity formed therein. The first cavity and the second cavity are connected to each other and externally expose the mounting pad.

### CROSS-REFERENCE TO RELATED APPLICATION

This application claims the priority and benefit of Korean Patent Application Nos. 10-2014-0099304 filed on Aug. 1, 2014 and 10-2014-0162759 filed on Nov. 20, 2014, with the Korean Intellectual Property Office, the disclosures of which are incorporated herein by reference.

### BACKGROUND

The present disclosure relates to an embedded board and a method of manufacturing the same.

As electronic devices, including mobile phones, used in the field of information technology (IT) are required to be multifunctionalized and are increasingly becoming slimmed and lightened, technology in which electronic components such as integrated circuits (ICs), semiconductor chips, active elements, passive elements, and the like, are embedded into boards has been required in order to satisfy the above-mentioned technical requirements, and a technology of embedding the components in the board using various methods has been developed.

In a general board in which components are embedded, a cavity is typically formed in an insulating layer of the board, and the electronic components, such as a variety of elements, the ICs, semiconductor chips, etc. may be inserted into the cavity.

### SUMMARY

An aspect of the present disclosure may provide an embedded board in which thickness adjustment may be facilitated and a method of manufacturing the same.

According to an aspect of the present disclosure, an embedded board may include: a core substrate below which a mounting pad is formed; a first substrate formed below the core substrate and having a first cavity formed therein; and a second substrate formed below the first substrate and having a second cavity formed therein, wherein the first cavity and the second cavity are connected to each other and cause the mounting pad to be externally exposed.

The embedded board may further include a first electronic element disposed in the cavity to be electrically connected to the mounting pad.

The second cavity has a diameter greater than that of the first cavity, such that a portion of a circuit layer of the first substrate may be externally exposed.

The embedded board may further include a second electronic element disposed in the second cavity.

The embedded board may further include a third electronic element mounted on the core substrate.

According to another aspect of the present disclosure, a method of manufacturing an embedded board may include: preparing a core substrate below which a mounting pad is formed; forming a protection layer to cover the mounting pad; forming a first substrate below the core substrate, wherein a first cavity into which the protection layer is inserted is formed in the first substrate; forming a second substrate below the first substrate, wherein a second cavity disposed below the first cavity is formed in the second substrate; and removing the protection layer, wherein the first cavity and the second cavity are connected to each other and cause the mounting pad to be externally exposed.

The method may further include: after the removing of the protection layer, electrically connecting a first electronic element to the mounting pad by disposing the first electronic element in the first cavity and the second cavity.

In the forming of the second substrate, the second cavity may have a diameter greater than that of the first cavity to externally expose a portion of a circuit layer of the first substrate.

The method may further include: after the electrically connecting of the first electronic element to the mounting pad, electrically connecting a second electronic element to a circuit layer of the second substrate externally exposed by disposing the second electronic element in the second cavity.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a view illustrating an embedded board according to an exemplary embodiment in the present disclosure;

FIGS. 2 through 20 are views illustrating a method of manufacturing an embedded board according to an exemplary embodiment in the present disclosure;

FIG. 21 is a view illustrating an embedded board according to another exemplary embodiment in the present disclosure;

FIGS. 22 through 30 are views illustrating a method of manufacturing an embedded board according to another exemplary embodiment in the present disclosure;

FIG. 31 is a view illustrating an embedded board on which an electronic element is disposed, according to a first exemplary embodiment in the present disclosure;

FIG. 32 is a view illustrating an embedded board on which an electronic element is disposed, according to a second exemplary embodiment in the present disclosure;

FIG. 33 is a view illustrating an embedded board on which electronic elements are disposed, according to a third exemplary embodiment in the present disclosure;

FIG. 34 is a view illustrating an embedded board on which electronic elements are disposed, according to a fourth exemplary embodiment in the present disclosure; and

FIG. 35 is a view illustrating an embedded board on which electronic elements are disposed, according to a fifth exemplary embodiment in the present disclosure.

### DETAILED DESCRIPTION

Hereinafter, embodiments in the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. In the drawings, the shapes and dimensions of elements may be exaggerated for clarity, and the same reference numerals will be used throughout to designate the same or like elements.

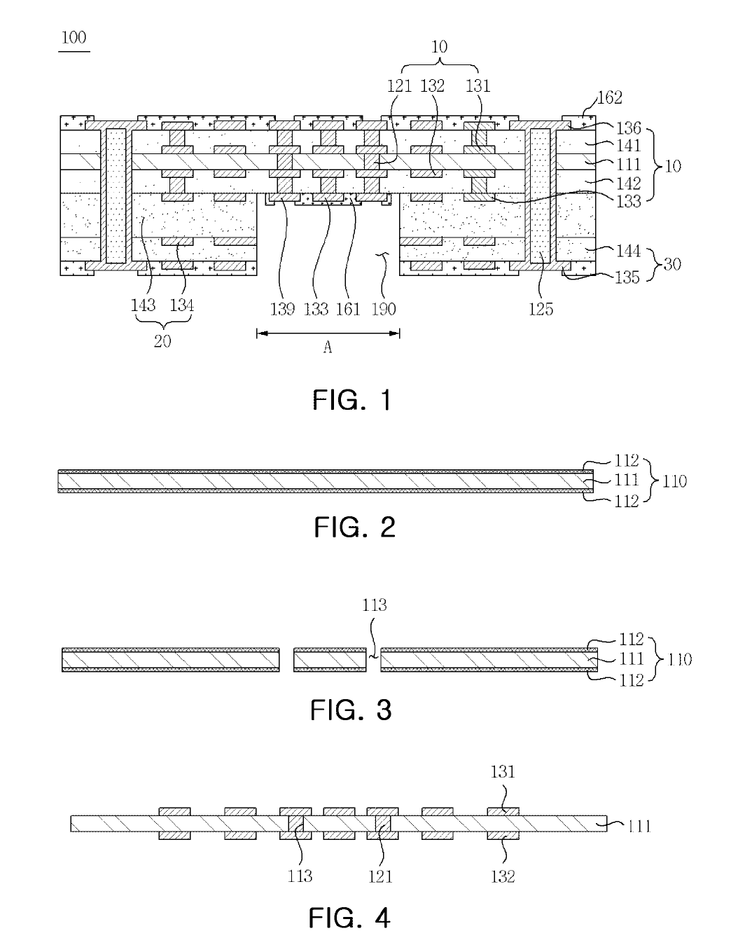

FIG. 1 is a view illustrating an embedded board according to an exemplary embodiment in the present disclosure.

Referring to FIG. 1, an embedded board 100 may include a core substrate 10, a first substrate 20, a second substrate 30, a first through via 121, a second through via 125, a first solder resist layer 161, and a second solder resist layer 162.

According to an exemplary embodiment in the present disclosure, the core substrate 10 may include a core insulating layer 111, a first insulating layer 141, a second insulating layer 142, a first circuit layer 131, a second circuit layer 132, a third circuit layer 133, and a sixth circuit layer 136. In addition, the first substrate 20 may include a third insulating layer 143 and a fourth circuit layer 134. In addition, the second substrate 30 may include a fourth insulating layer 144 and a fifth circuit layer 135.

According to an exemplary embodiment in the present disclosure, the first substrate 20 is formed below the core substrate 10, and the second substrate 30 is formed below the first substrate 20. In addition, a cavity 190 having a through structure is formed in the first substrate 20 and the second substrate 30.

According to an exemplary embodiment in the present disclosure, the first insulating layer 141 is formed on the core insulating layer 111. In addition, the second insulating layer 142 is formed below the core insulating layer 111. The first insulating layer 141, the second insulating layer 142, and the core insulating layer 111 according to an exemplary embodiment in the present disclosure may be formed using a complex polymer resin which is generally used as an interlayer insulating material. For example, the first insulating layer 141, the second insulating layer 142, and the core insulating layer 111 may be formed of pre-preg, Ajinomoto Build-up Film (ABF), or an epoxy based resin such as FR-4, Bismaleimide Triazine (BT), or the like.

According to an exemplary embodiment in the present disclosure, the first circuit layer 131 may be formed on the core insulating layer 111 and may be embedded in the first insulating layer 141. In addition, the second circuit layer 132 may be formed below the core insulating layer 111 and may be embedded in the second insulating layer 142.

According to an exemplary embodiment in the present disclosure, the third circuit layer 133 may be formed below the second insulating layer 142.

According to an exemplary embodiment in the present disclosure, the third circuit layer 133 may include a mounting pad 139. According to an exemplary embodiment in the present disclosure, the mounting pad 139 may be a circuit pattern on which external components such as an electronic element and a semiconductor package are mounted to be electrically connectable to each other. The mounting pad 139 may be formed in a mounting area A. Here, the mounting area A is an area of the embedded board 100 in which the external components are mounted and disposed.

According to an exemplary embodiment in the present disclosure, the third insulating layer 143 may be an insulating layer of the first substrate 20. According to an exemplary embodiment in the present disclosure, the third insulating layer 143 may be formed below the second insulating layer 142 to embed the third circuit layer 133. Here, the cavity 190 may be formed in the mounting area A of the second insulating layer 142. Therefore, the second insulating layer 142 may expose the third circuit layer 133 including the mounting pad 139 formed externally in the mounting area A.

According to an exemplary embodiment in the present disclosure, the fourth insulating layer 144 may be an insulating layer of the second substrate 30. According to an exemplary embodiment in the present disclosure, the fourth insulating layer 144 may be formed below the third insulating layer 143 to embed the fourth circuit layer 134. According to an exemplary embodiment in the present disclosure, the cavity 190 may be formed in the mounting area A of the fourth insulating layer 144 to externally expose the mounting pad 139 of the third circuit layer 133.

That is, according to an exemplary embodiment in the present disclosure, the cavity 190 having the through structure may be formed in the mounting area A of the third insulating layer 143 and the fourth insulating layer 144.

According to an exemplary embodiment in the present disclosure, the third insulating layer 143 and the fourth insulating layer 144 may be formed of a no-flow type pre-preg. Therefore, although the third insulating layer 143 and the fourth insulating layer 144 are formed to be thin or thick, a shape of the cavity 190 may be maintained.

According to an exemplary embodiment in the present disclosure, the fourth circuit layer 134 may be a circuit layer of the first substrate 20. According to an exemplary embodiment in the present disclosure, the fourth circuit layer 134 may be formed below the third insulating layer 143 to be embedded in the fourth insulating layer 144.

According to an exemplary embodiment in the present disclosure, the fifth circuit layer 135 may be a circuit layer of the second substrate 30. According to an exemplary embodiment in the present disclosure, the fifth circuit layer 135 may be formed below the fourth insulating layer 144.

In addition, according to an exemplary embodiment in the present disclosure, the sixth circuit layer 136 may be formed on the first insulating layer 141.

The first circuit layer 131 to the sixth circuit layer 136, according to an exemplary embodiment in the present disclosure formed as described above may be formed of a conductive metal which is typically used in the field of circuit boards. For example, the first circuit layer 131 to the sixth circuit layer 136 may be formed of copper.

According to an exemplary embodiment in the present disclosure, the first through via 121 may penetrate through the core insulating layer 111. The first through via 121 may penetrate through the core insulating layer 111 to electrically connect the first circuit layer 131 and the second circuit layer 132 to each other.

According to an exemplary embodiment in the present disclosure, the second through via 125 may penetrate through all of the first insulating layer 141 to the fourth insulating layer 144. The fifth circuit layer 135 and the sixth circuit layer 136 may be electrically connected to each other by the second through via 125 formed as described above. In addition, although not shown, the first circuit layer 131 to the sixth circuit layer 136 may also be electrically connected to one another by the second through via 125.

According to an exemplary embodiment in the present disclosure, the first through via 121 and the second through via 125 may include a conductive material. According to an exemplary embodiment in the present disclosure, the second through via 125 may have a structure in which an outer wall thereof is formed of a conductive metal and an inner portion thereof is filled with a plugging material. However, the second through via 125 is not necessarily limited to the structure in which both the conductive metal and the plugging material are used. The second through via 125 may also be formed in any structure as long as it may electrically connect between different layers.

According to an exemplary embodiment in the present disclosure, the first solder resist layer 161 may be formed below the second insulating layer 142 disposed in the mounting area A. That is, the first solder resist layer 161 may be formed below the second insulating layer 142 exposed by the cavity 190. According to an exemplary embodiment in the present disclosure, the first solder resist layer 161 may cover and protect the third circuit layer 133 of the mounting area A, and the mounting pad 139 may be externally exposed.

In addition, according to, the second solder resist layer 162 may be formed on the first insulating layer 141 to protect the sixth circuit layer 136 from the outside. In addition, the second solder resist layer 162 may be formed below the fourth insulating layer 144 to protect the fifth circuit layer 135 from the outside. According to an exemplary embodiment in the present disclosure, the second solder resist layer 162 may be formed so that a portion which is electrically connected to the external component among the fifth circuit layer 135 and the sixth circuit layer 136 is externally exposed.

According to an exemplary embodiment in the present disclosure, the first solder resist layer 161 and the second solder resist layer 162 may protect a circuit pattern from a soldering process when the external component is mounted.

According to an exemplary embodiment in the present disclosure, the first solder resist layer 161 and the second solder resist layer 162 may be formed of a heat-resistant covering material.

FIGS. 2 through 20 are views illustrating a method of manufacturing an embedded board according to an exemplary embodiment in the present disclosure.

Referring to FIG. 2, a metal laminate 110 may be provided.

According to an exemplary embodiment in the present disclosure, the metal laminate 110 may have a core metal layer 112 formed on both surfaces of the core insulating layer 111.

According to an exemplary embodiment in the present disclosure, the core insulating layer 111 may be formed of a complex polymer resin which is typically used as an interlayer insulating material. For example, the core insulating layer 111 may be formed of pre-preg, Ajinomoto Build-up Film (ABF), or an epoxy based resin such as FR-4, Bismaleimide Triazine (BT), or the like.

According to an exemplary embodiment in the present disclosure, the core metal layer 112 may be formed of a conductive metal which is typically used in the field of circuit boards. For example, the core metal layer 112 may be formed of copper.

Referring to FIG. 3, a first through hole 113 may be formed.

According to an exemplary embodiment in the present disclosure, the first through hole 113 may penetrate through the metal laminate 110. According to an exemplary embodiment in the present disclosure, the first through hole 113 may be formed with the use of a computerized numerical control (CNC) drilling device. However, the first through hole 113 is not limited to being formed with the use of the CNC drilling device. The first through hole 113 may be formed by any method of forming the through hole which is known in the field of circuit boards.

Referring to FIG. 4, the first through via 121, the first circuit layer 131, and the second circuit layer 132 may be formed.

According to an exemplary embodiment in the present disclosure, the first through via 121 may be formed in the first through hole 113 (FIG. 3). In addition, the first circuit layer 131 may be formed on the core insulating layer 111, and the second circuit layer 132 may be formed below the core insulating layer 111. According to an exemplary embodiment in the present disclosure, the first circuit layer 131 and the second circuit layer 132 may be formed by patterning the core metal layers 112 (FIG. 3) of the metal laminate 110 (FIG. 3). Alternatively, the first circuit layer 131 and the second circuit layer 132 may be formed by patterning the core metal layers 112 (FIG. 3) after a plating is performed on the core metal layers 112 (FIG. 3).

According to an exemplary embodiment in the present disclosure, the first through via 121, the first circuit layer 131, and the second circuit layer 132 may be formed by a method of forming a circuit which is known in the field of circuit boards. For example, the first through via 121, the first circuit layer 131, and the second circuit layer 132 may be formed by a tenting process, a semi-additive process (SAP), or a modified semi-additive process (MSAP).

According to an exemplary embodiment in the present disclosure, the first through via 121, the first circuit layer 131, and the second circuit layer 132 may be formed of a conductive metal which is typically used in the field of circuit boards. For example, the first through via 121, the first circuit layer 131, and the second circuit layer 132 may be formed of copper.

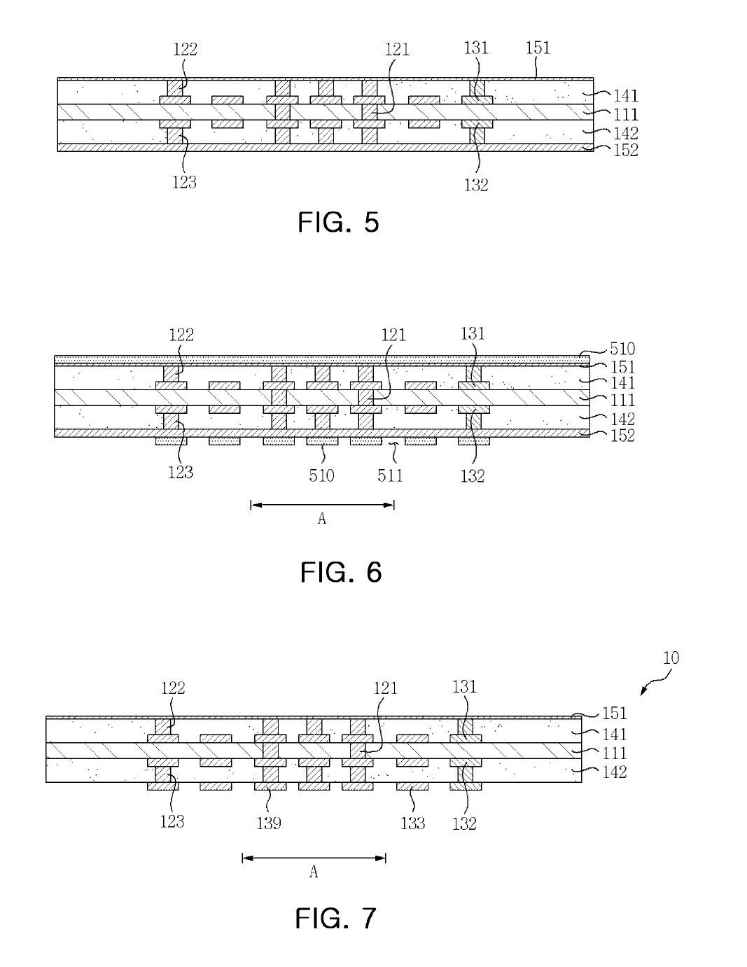

Referring to FIG. 5, the first insulating layer 141, the second insulating layer 142, the first via 122, the second via 123, the first metal layer 151, and the second metal layer 152 may be formed.

According to an exemplary embodiment in the present disclosure, the first insulating layer 141 may be formed on the core insulating layer 111. In this case, the first insulating layer 141 may embed the first circuit layer 131. In addition, the second insulating layer 142 may be formed below the core insulating layer 111. In this case, the second insulating layer 142 may embed the second circuit layer 132.

According to an exemplary embodiment in the present disclosure, the first insulating layer 141 and the second insulating layer 142 may be formed by being individually stacked and compressed on and below, respectively, the core insulating layer 111 in a film form. Alternatively, the first insulating layer 141 and the second insulating layer 142 may be formed by being individually applied on and below, respectively, the core insulating layer 111 in a liquefied form.

According to an exemplary embodiment in the present disclosure, the first insulating layer 141 and the second insulating layer 142 may be formed of a complex polymer resin which is typically used as an interlayer insulating material. For example, the first insulating layer 141 and the second insulating layer 142 may be formed of pre-preg, Ajinomoto Build-up Film (ABF), or an epoxy based resin such as FR-4, Bismaleimide Triazine (BT), or the like.

According to an exemplary embodiment in the present disclosure, the via holes (not shown) may be formed in the first insulating layer 141 and the second insulating layer 142, respectively.

Then, the via holes (not shown) are plated, such that the first via 122 may be formed in the first insulating layer 141 and the second via 123 may be formed in the second insulating layer 142.

When the via holes (not shown) are plated, the plating may be simultaneously performed on the first insulating layer 141 and below the second insulating layer 142. In this case, the first metal layer 151 may be formed on the first insulating layer 141, and the second metal layer 152 may be formed below the second insulating layer 142.

Alternatively, the first metal layer 151 and the second metal layer 152 may also be formed by stacking and compressing a metal foil on the first insulating layer 141 and below the second insulating layer 142, respectively, after the first via 122 and the second via 123 are formed.

According to an exemplary embodiment in the present disclosure, the first via 122 may penetrate through the first insulating layer 141 to electrically connect the first circuit layer 131 and the first metal layer 151 to each other. In addition, the second via 123 may penetrate through the second insulating layer 142 to electrically connect the second circuit layer 132 and the second metal layer 152 to each other.

According to an exemplary embodiment in the present disclosure, the first via 122, the second via 123, the first metal layer 151, and the second metal layer 152 may be formed of a conductive metal which is typically used in the field of circuit boards. For example, the first via 122, the second via 123, the first metal layer 151, and the second metal layer 152 may be formed of copper.

FIG. 5 illustrates a case in which a thickness of the second metal layer 152 is thicker than that of the first metal layer 151. However, the thickness of the second metal layer 152 may also be the same as that of the first metal layer 151, or the second metal layer 152 may be thinner than that of the first metal layer 151.

Referring to FIG. 6, a first etching resist 510 may be formed.

According to an exemplary embodiment in the present disclosure, the first etching resist 510 may cover an entire upper surface of the first metal layer 151. This is to protect the first metal layer 151 from an etchant when an etching process is performed.

In addition, according to an exemplary embodiment in the present disclosure, the first etching resist 510 may be formed below the second metal layer 152. In this case, a first opening 511 may be formed in the first etching resist 510. Here, the first etching resist 510 may protect a region in which a circuit pattern of a third circuit layer (not shown) is to be formed. In addition, the first opening 511 of the first etching resist 510 may externally expose a portion to be removed from the second metal layer 152.

Referring to FIG. 7, the third circuit layer 133 may be formed.

According to an exemplary embodiment in the present disclosure, the etching process may be performed. In this case, the portions exposed by the first etching resist 510 (FIG. 6) may be removed from the second metal layer 152 (FIG. 6). As such, the second metal layer 152 (FIG. 6) may be patterned to become the third circuit layer 133. When the etching process is finished, the first etching resist 510 (FIG. 6) may be removed.

According to an exemplary embodiment in the present disclosure, the third circuit layer 133 may include the mounting pad 139. Here, the mounting pad 139 may be formed in the mounting area A and may be a circuit pattern on which external components such as an electronic element and a semiconductor package are mounted to be electrically connectable to each other.

Here, the third circuit layer 133 may be electrically connected to the second circuit layer 132 by the second via 123.

According to an exemplary embodiment in the present disclosure, the core substrate 10 of FIG. 1 may be formed according to FIGS. 2 through 7. According to an exemplary embodiment in the present disclosure, the core substrate 10 may include the core insulating layer 111, the first insulating layer 141, the second insulating layer 142, the first circuit layer 131, the second circuit layer 132, and the third circuit layer 133. In addition, the core substrate 10 may further include a sixth circuit layer (not shown) which is not formed in the present operation, but is formed later.

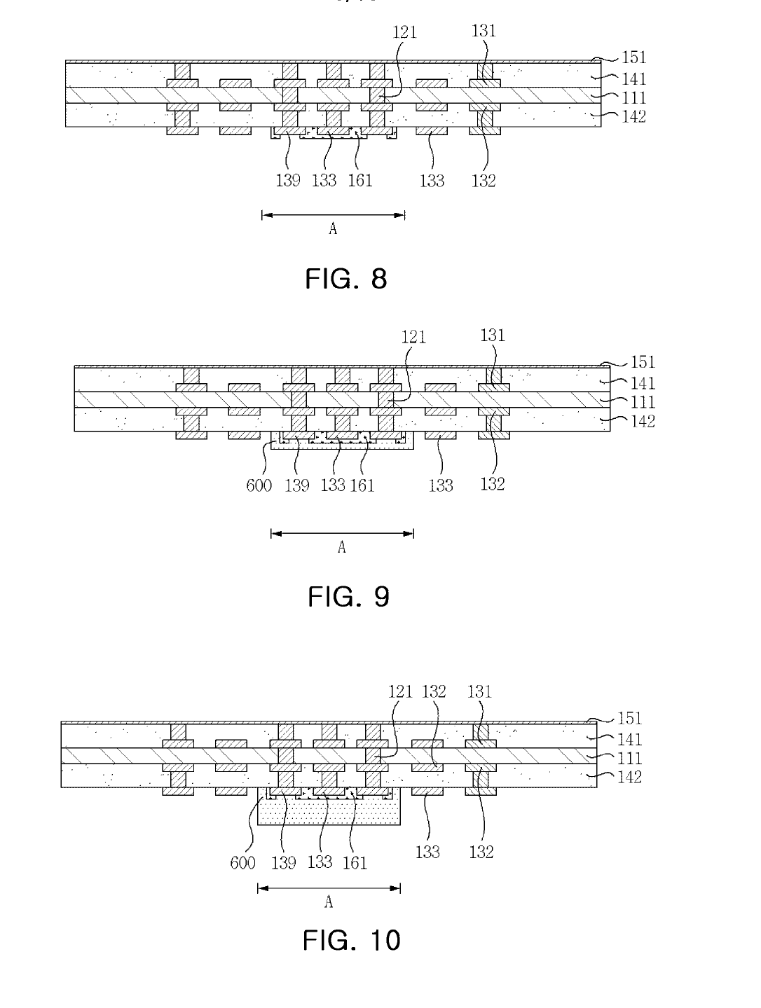

Referring to FIG. 8, the first solder resist layer 161 may be formed.

According to an exemplary embodiment in the present disclosure, the first solder resist layer 161 may be formed in the mounting area A to cover and protect the third circuit layer 133. In this case, the first solder resist layer 161 may externally expose the mounting pad 139.

According to an exemplary embodiment in the present disclosure, the first solder resist layer 161 may protect the third circuit layer 133 formed in the mounting area A from the soldering process when the external component is mounted. In addition, the first solder resist layer 161 may serve as a dam which prevents the third circuit layer 133 from being short circuited with a neighboring mounting pad 139, which may be caused due to the use of an excessive amount of solder in the soldering process.

According to an exemplary embodiment in the present disclosure, the first solder resist layer 161 may be formed of a heat-resistant covering material.

Referring to FIGS. 9 and 10, a protection layer 600 may be formed.

According to an exemplary embodiment in the present disclosure, the protection layer 600 may be formed in the mounting area A. The protection layer 600 may surround the first solder resist layer 161 and the mounting pad 139 of the mounting area A. The protection layer 600 formed as described above may protect the mounting pad 139 from the outside. For example, the protection layer 600 may prevent the mounting pad 139 from being damaged by the etchant by preventing the etchant from coming in contact with the mounting pad 139 when the etching process is performed.

According to an exemplary embodiment in the present disclosure, the protection layer 600 may be formed of a high heat-resistant material. Therefore, in a case in which a flow of an insulating layer formed below the third circuit layer 133 occurs by relatively high temperature, the protection layer 600 may prevent the insulating layer from flowing into the mounting pad 139. For example, the protection layer 600 may be formed of a high heat-resistant dry film.

In addition, according to an exemplary embodiment in the present disclosure, the protection layer 600 is formed to be thin, but may also be formed to be thick as shown in FIG. 10. In a case in which the protection layer 600 is formed to be thick as shown in FIG. 10, the protection layer 600 may more efficiently prevent the flow of the insulating layer. Subsequent operations will be shown and described based on FIG. 9.

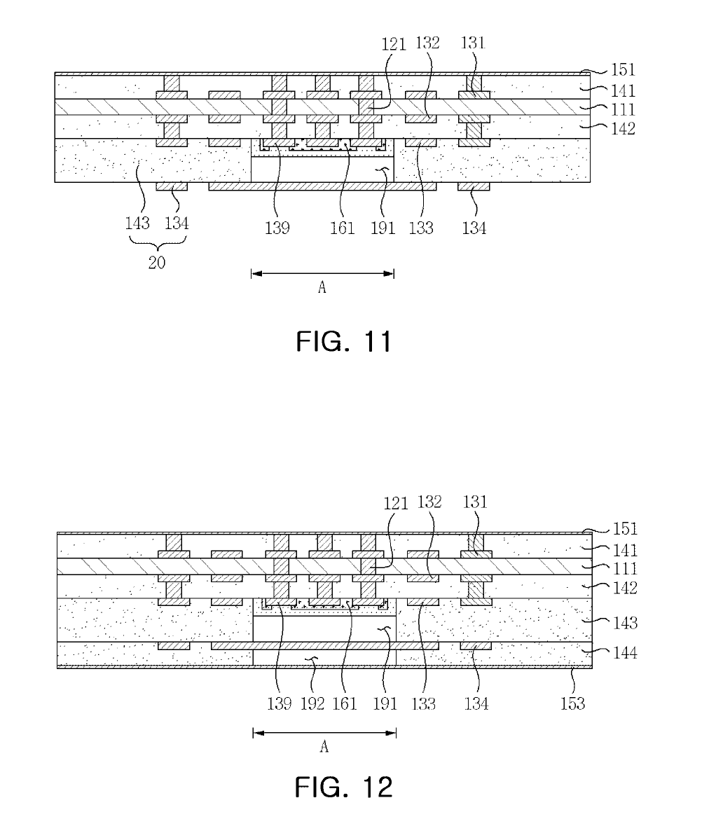

Referring to FIG. 11, the third insulating layer 143 and the fourth circuit layer 134 may be formed.

According to an exemplary embodiment in the present disclosure, the third insulating layer 143 may be stacked below the second insulating layer 142 and the third circuit layer 133 after an area corresponding to the mounting area A has been punched out. Here, the punched-out portion of the third insulating layer 143 may be a first cavity 191, and the first cavity 191 may be formed so that the protection layer 600 is inserted into the first cavity 191.

According to an exemplary embodiment in the present disclosure, the third insulating layer 143 may be formed of a no-flow type pre-preg having low flowability. Here, a degree of flowability of the third insulating layer 143 may be referred to as a degree at which a form of the third insulating layer 143 may be maintained even though a punching process is performed. By using the pre-preg having low flowability as described above, a thickness of the third insulating layer 143 may be easily adjusted.

In addition, according to an exemplary embodiment in the present disclosure, even if the third insulating layer 143 is formed of the pre-preg having low flowability, the flow of the third insulating layer 143 may occur due to heating and compress processes during stacking. In this case, the protection layer 600 may protect the third insulating layer 143 from flowing into the mounting area A. That is, the protection layer 600 may serve as the dam which prevents the flow of the third insulating layer 143. An occurrence of a defect caused by the third insulating layer 143 covering the mounting pad 139 may be prevented by the protection layer 600 as described above.

According to an exemplary embodiment in the present disclosure, the fourth circuit layer 134 may be formed below the third insulating layer 143. According to an exemplary embodiment in the present disclosure, the fourth circuit layer 134 may be formed by stacking and then patterning a copper foil below the third insulating layer 143. However, forming of the fourth circuit layer 134 is not limited to the above-mentioned method. The fourth circuit layer 134 may be formed by any methods of forming a circuit layer which is known in the field of circuit boards.

According to an exemplary embodiment in the present disclosure, the fourth circuit layer 134 may include a circuit pattern blocking a lower portion of the first cavity 191. As such, the circuit pattern blocking the lower portion of the first cavity 191 may prevent chemicals such as the etchant from being introduced into the first cavity 191 in subsequent processes. Therefore, chemical damage to the configuration portion exposed by the first cavity 191 may be prevented.

Although an exemplary embodiment in the present disclosure describes the case in which the fourth circuit layer 134 is, by way of example, formed by a tenting process, the process of forming the fourth circuit layer 134 is not limited thereto. That is, the fourth circuit layer 134 may also be formed by a semi-additive process (SAP) or a modified semi-additive process (MSAP).

According to an exemplary embodiment in the present disclosure, the third insulating layer 143 and the fourth circuit layer 134 may become the first substrate 20 of FIG. 1.

Referring to FIG. 12, the fourth insulating layer 144 and the third metal layer 153 may be formed.

According to an exemplary embodiment in the present disclosure, the fourth insulating layer 144 may be stacked below the third insulating layer 143 and the fourth circuit layer 134 in a state in which an area corresponding to the mounting area A has been punched out. Here, the punched-out portion of the fourth insulating layer 144 may be a second cavity 192, and the second cavity 192 may be formed below the first cavity 191.

According to an exemplary embodiment in the present disclosure, the fourth insulating layer 144 may be formed of a no-flow type pre-preg having low flowability. Here, a degree of flowability of the fourth insulating layer 144 may be referred to a degree at which a form of the fourth insulating layer 144 may be maintained even though a punching process is performed. By using the pre-preg having low flowability as described above, a thickness of the fourth insulating layer 144 may be easily adjusted.

In addition, as the thicknesses of the third insulating layer 143 and the fourth insulating layer 144 are adjusted by using the pre-preg having low flowability in an exemplary embodiment in the present disclosure, depths of the first cavity 191 and the second cavity 192 in which the external components are mounted may be easily adjusted.

According to an exemplary embodiment in the present disclosure, the third metal layer 153 may be formed below the fourth insulating layer 144. In addition, the third metal layer 153 may be formed to block a lower portion of the second cavity 192 of the fourth insulating layer 144. According to an exemplary embodiment in the present disclosure, the third metal layer 153 may be formed of a conductive metal which is used in the field of circuit boards. For example, the third metal layer 153 may be formed of copper.

According to an exemplary embodiment in the present disclosure, after the fourth insulating layer 144 in which the second cavity 192 is formed is stacked below the third insulating layer 143, the third metal layer 153 of a metal foil form may be stacked below the fourth insulating layer 144.

Alternatively, after the third metal layer 153 of a metal foil form is stacked below the fourth insulating layer 144 in which the second cavity 192 is formed, the fourth insulating layer 144 on which the third metal layer 153 is formed may be stacked below the third insulating layer 143.

Alternatively, after the third metal layer 153 is formed below the fourth insulating layer 144, the second cavity 192 may be formed in the fourth insulating layer 144. Thereafter, the fourth insulating layer 144 on which the third metal layer 153 is formed may be stacked below the third insulating layer 143. Here, the third metal layer 153 may be formed by being plated on the fourth insulating layer 144 or being stacked on the fourth insulating layer 144 in the metal foil form.

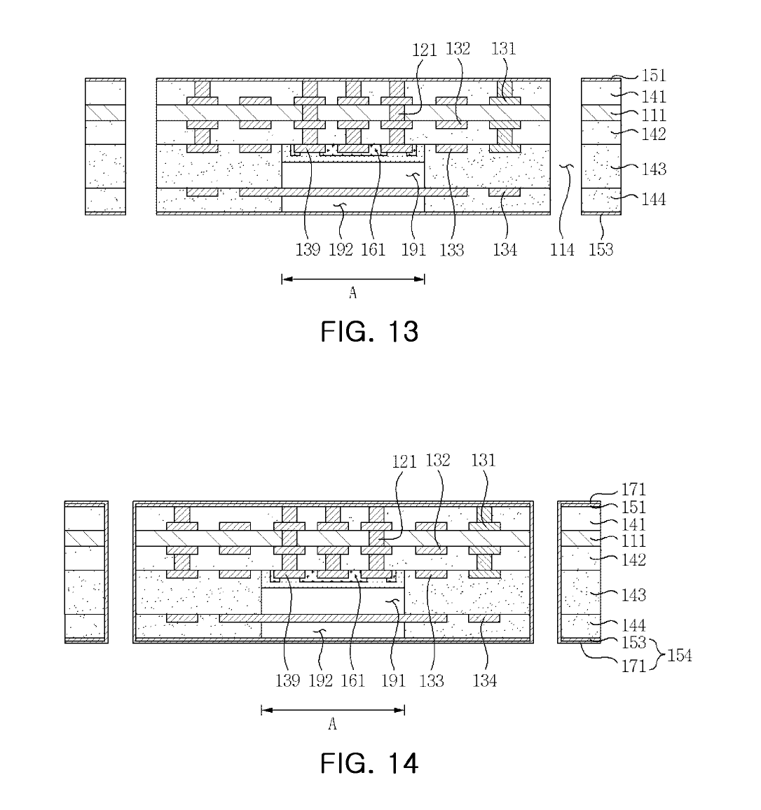

Referring to FIG. 13, a second through hole 114 may be formed.

According to an exemplary embodiment in the present disclosure, the second through hole 114 may penetrate through the first metal layer 151 to the third metal layer 153.

According to an exemplary embodiment in the present disclosure, the second through hole 114 may be formed with the use of a CNC drilling device. However, the second through hole 114 is not limited to being formed with the use of the CNC drilling device. The second through hole 114 may be formed by any method of forming the through hole which is known in the field of circuit boards.

Referring to FIG. 14, a plating process may be performed.

According to an exemplary embodiment in the present disclosure, the plating process is performed, such that a first plated layer 171 may be formed on a wall surface of the second through hole 114, on the first metal layer 151, and below the third metal layer 153.

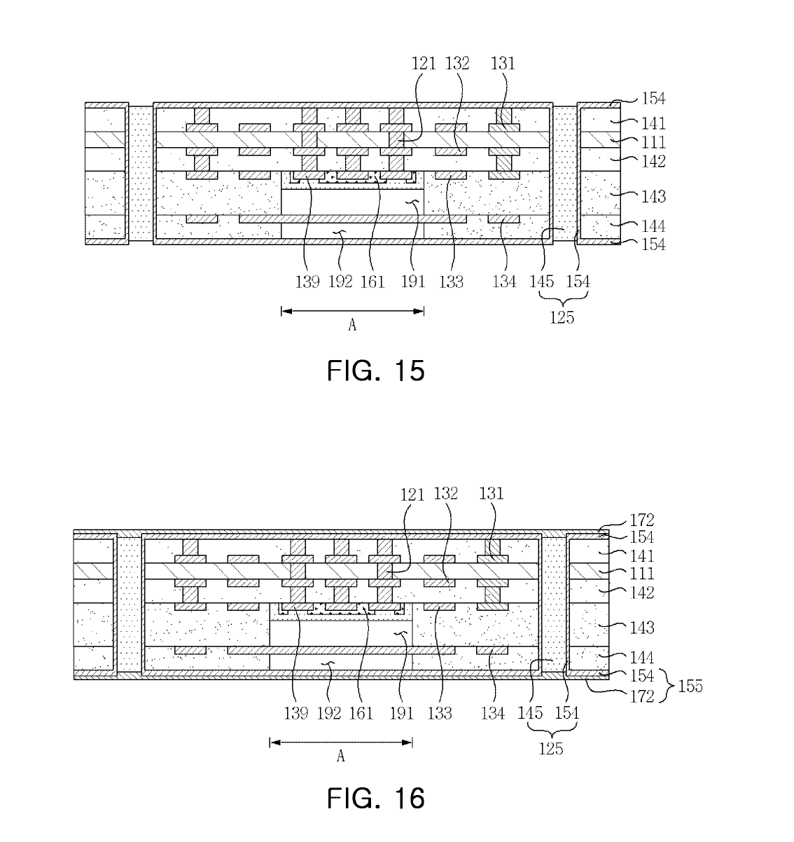

From FIG. 15, the first plated layer 171 formed on the wall surface of the second through hole 114, the first plated layer 171 and the first metal layer 151 formed on the first insulating layer 141, and the first plated layer 171 and the third metal layer 153 formed below the fourth insulating layer 144 will be all shown and described by being incorporated as a fourth metal layer 154, for convenience of explanation.

Referring to FIG. 15, a plugging may be performed.

According to an exemplary embodiment in the present disclosure, the second through hole 114 (FIG. 14) on which the fourth metal layer 154 is formed may be filled with a plugging material 145. According to an exemplary embodiment in the present disclosure, the plugging material 145 may be provided to have a height lower than a lower surface or an upper surface of the fourth metal layer 154 as shown in FIG. 15. Alternatively, the plugging material 145 may be formed to overflow the lower surface or the upper surface of the fourth metal layer 154. In this case, the plugging material 145 may be provided only in the second through hole 114 (FIG. 14) by removing the plugging material 145 overflowing the lower surface or the upper surface of the fourth metal layer 154 by a polishing process.

According to an exemplary embodiment in the present disclosure, the fourth metal layer 154 and the plugging material 145 formed in the second through hole 114 (FIG. 14) may become the second through via 125.

Referring to FIG. 16, the plating may be performed.

According to an exemplary embodiment in the present disclosure, the plating is performed, such that a second plated layer 172 may be formed below and on the fourth metal layer 154. In this case, the second plated layer 172 may also be formed and provided in a portion in which the plugging material 145 is not provided in the second through hole 114 (FIG. 15). Flatness may be improved by the second plated layer 172 being formed as described above.

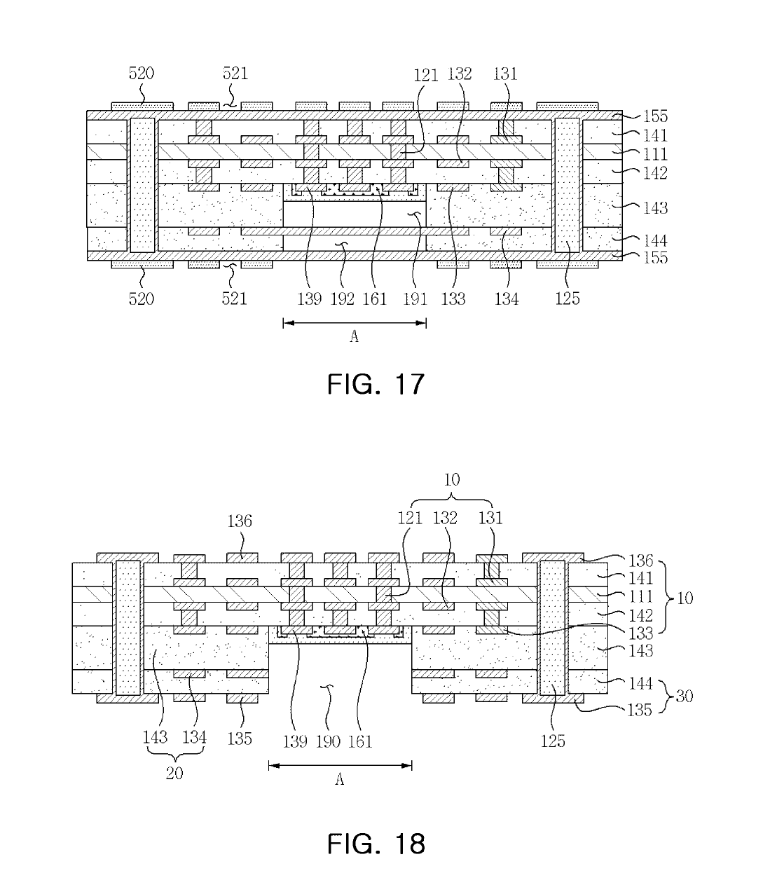

From FIG. 17, the fourth metal layer 154 and the second plated layer 172 will be shown and described by being incorporated as a fifth metal layer 155 for convenience of explanation and understanding.

Referring to FIG. 17, a second etching resist 520 may be formed.

According to an exemplary embodiment in the present disclosure, the second etching resist 520 may be formed on the fifth metal layer 155 formed on the first insulating layer 141. In addition, the second etching resist 520 may be formed below the fifth metal layer 155 formed below the fourth insulating layer 144.

According to an exemplary embodiment in the present disclosure, the second etching resist 520 may include a second opening 521. The second etching resist 520 may protect regions that circuit patterns of a fifth circuit layer (not shown) and a sixth circuit layer (not shown) are to be formed on the fifth metal layer 155, and the second opening 521 is disposed on regions from which the second etching resist 520 is removed, such that the fifth metal layer 155 may be externally exposed.

Referring to FIG. 18, a fifth circuit layer 135 and a sixth circuit layer 136 may be formed.

According to an exemplary embodiment in the present disclosure, the etching process may be performed. In this case, the portions exposed by the second etching resist 520 (FIG. 17) may be removed from the fifth metal layer 155 (FIG. 17). The fifth circuit layer 135 may be formed below the fourth insulating layer 144 by the etching process as described above. In addition, the sixth circuit layer 136 may be formed on the first insulating layer 141.

In addition, when the fifth circuit layer 135 and the sixth circuit layer 136 are formed, the circuit pattern blocking the lower portion of the first cavity 191 and the portion blocking the lower portion of the second cavity 192 of the third metal layer 153 are removed, such that one cavity 190 may be formed.

When the etching process is finished, the second etching resist 520 (FIG. 17) may be removed.

According to an exemplary embodiment in the present disclosure, the fourth insulating layer 144 and the fifth circuit layer 135 formed below the first substrate 20 may become the second substrate 30. In addition, the sixth circuit layer 136 may be included in the core substrate 10.

According to an exemplary embodiment in the present disclosure, a case in which the core substrate 10 includes three insulating layers and four circuit layers, and the first substrate 20 and the second substrate 30 include one insulating layer and one circuit layer, has been described by way of example. However, the number of layers of the insulating layers and the circuit layers of the core substrate 10, the first substrate 20, and the second substrate 30 is not limited thereto. That is, the number of layers of the insulating layers and the circuit layers of the core substrate 10, the first substrate 20, and the second substrate 30 may be changed depending on a selection by those skilled in the art.

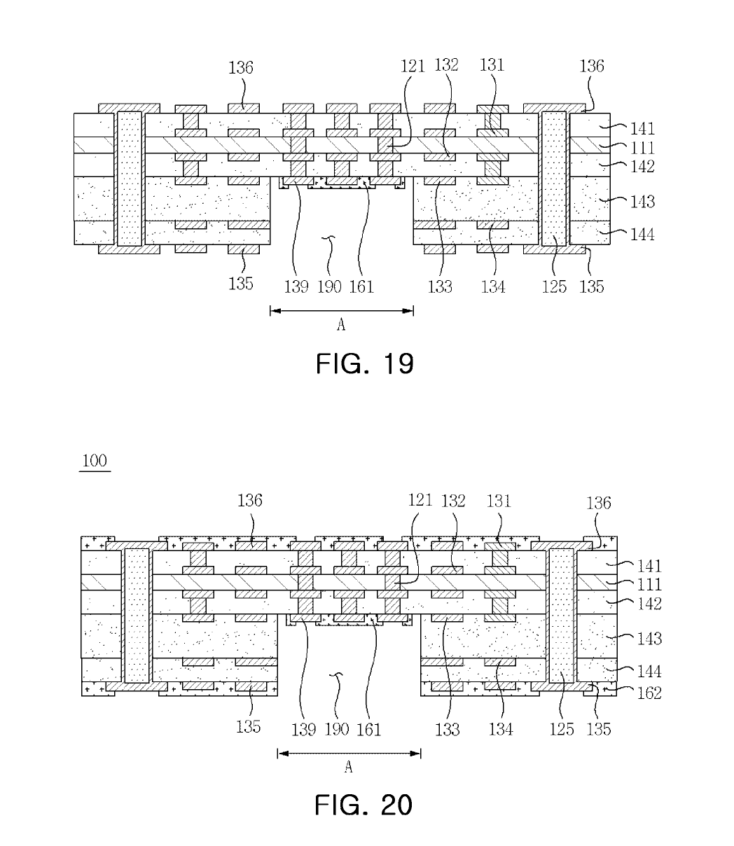

Referring to FIG. 19, the protection layer 600 (FIG. 18) may be removed.

According to an exemplary embodiment in the present disclosure, in a case in which the protection layer 600 (FIG. 18) is removed, the mounting pad 139 may be externally exposed.

Referring to FIG. 20, the second solder resist layer 162 may be formed.

According to an exemplary embodiment in the present disclosure, the second solder resist layer 162 may be formed on the first insulating layer 141 and below the fourth insulating layer 144 to cover and protect the fifth circuit layer 135 and the sixth circuit layer 136 from being externally exposed. In this case, the second solder resist layer 162 may be formed so that a portion which is electrically connected to the external component among the fifth circuit layer 135 and the sixth circuit layer 136 is externally exposed. According to an exemplary embodiment in the present disclosure, the second solder resist layer 162 may be formed of a heat-resistant covering material.

The embedded board 100 of FIG. 1 may be formed by the operations of FIGS. 2 through 20 as described above.

According to an exemplary embodiment in the present disclosure, after the protection layer 600 (FIG. 18) is removed, the second solder resist layer 162 may be formed. However, the second solder resist layer 162 may also be formed before the protection layer 600 (FIG. 18) is removed.

In addition, although not shown in an exemplary embodiment in the present disclosure, a surface treatment layer may be formed on the circuit pattern externally exposed among the circuit layers of the embedded board 100 of FIG. 1 or 20.

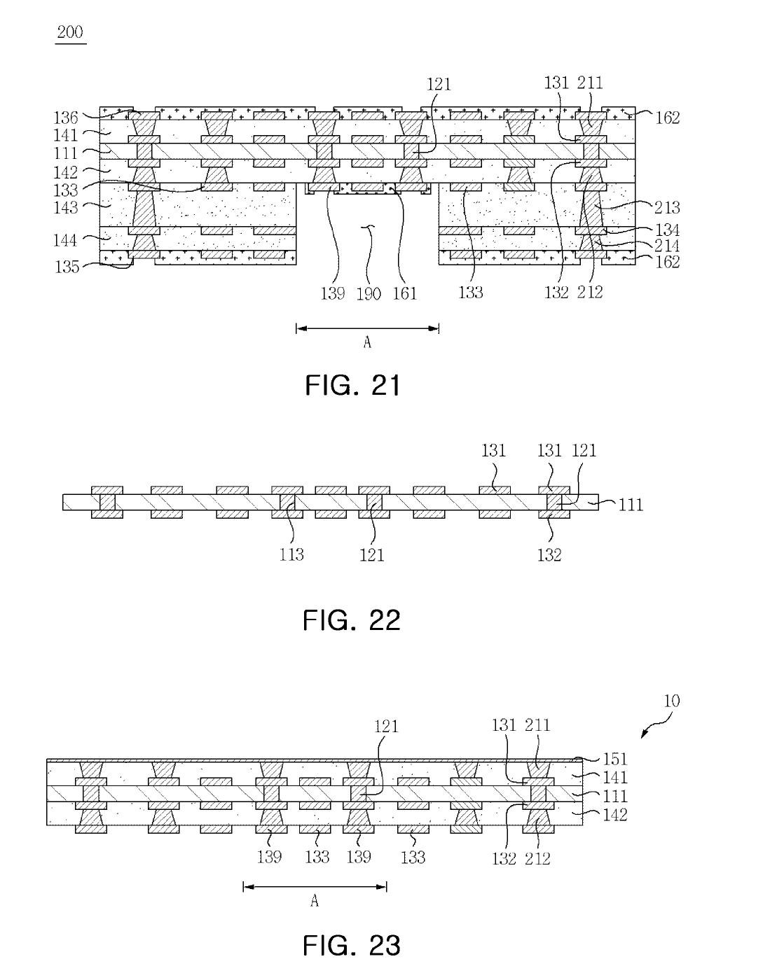

FIG. 21 is a view illustrating an embedded board according to another exemplary embodiment in the present disclosure.

In an embedded board 200 according to another exemplary embodiment in the present disclosure, the same configuration as that of the embedded substrate 100 of FIG. 1 will be denoted by the same reference numerals, and a description of the same configuration will be omitted. FIG. 21 will be described based on a difference between the embedded board 200 and the embedded board 100 of FIG. 1.

The embedded board 200, according to another exemplary embodiment in the present disclosure, is different from the embedded board 100 of FIG. 1 in that the configuration parts which electrically connect a circuit layer formed on the uppermost layer and a circuit layer formed on the lowest layer are different from each other. That is, in the embedded board 100 of FIG. 1, the second through via 125 (FIG. 1) may electrically connect the circuit layers on the uppermost layer and the lowest layer to each other. However, in the embedded board 200, according to the present exemplary embodiment, a plurality of vias and circuit layers may be stacked to electrically connect the circuit layers on the uppermost layer and the lowest layer to each other.

According to another exemplary embodiment in the present disclosure, the fifth circuit layer 135, which is the uppermost circuit layer of the embedded board 200, and the sixth circuit layer 136, which is the lowest circuit layer of the embedded board 200, may be electrically connected to each other by the first through via 121 and the first via 211 to the fourth via 214.

According to another exemplary embodiment in the present disclosure, the first via 211 may be formed in the first insulating layer 141. The first via 211 may electrically connect the first circuit layer 131 and the sixth circuit layer 136 to each other.

In addition, according to another exemplary embodiment in the present disclosure, the second via 212 may be formed in the second insulating layer 142. The second via 212 may electrically connect the second circuit layer 132 and the third circuit layer 133 to each other.

According to another exemplary embodiment in the present disclosure, the third via 213 may be formed in the third insulating layer 143. The third via 213 may electrically connect the third circuit layer 133 and the fourth circuit layer 134 to each other.

In addition, according to another exemplary embodiment in the present disclosure, the fourth via 214 may be formed in the fourth insulating layer 144. The fourth via 214 may electrically connect the fourth circuit layer 134 and the fifth circuit layer 135 to each other.

The first via 211 to the fourth via 214, according to another exemplary embodiment in the present disclosure, may be simultaneously formed when the insulating layers and the circuit layers of the respective layers are formed. The first via 211 to the fourth via 214 may be formed by any method as long as it is a method of forming a via which is known in the field of circuit boards.

According to another exemplary embodiment in the present disclosure, in a case in which the circuit layers of the uppermost layer and the lowest layer are electrically connected to each other by stacking the plurality of vias and circuit layers, a process of machining the through hole may be omitted. Therefore, stress due to the through hole machining and, accordingly, occurrences of defects may be prevented. In addition, according to another exemplary embodiment in the present disclosure, since a process of forming the through via such as a separate through hole machining and plating process, or the like, is omitted, time and costs may be reduced.

FIGS. 22 through 30 are views illustrating a method of manufacturing an embedded board according to another exemplary embodiment in the present disclosure.

Referring to FIG. 22, the first through via 121, the first circuit layer 131, and the second circuit layer 132 may be formed in the core insulating layer 111.

According to another exemplary embodiment in the present disclosure, the first circuit layer 131 may be formed on the core insulating layer 111 and the second circuit layer 132 may be formed below the core insulating layer 111. In addition, the first through via 121 may penetrate through the first core insulating layer 111 to electrically connect the first circuit layer 131 and the second circuit layer 132 to each other.

According to an exemplary embodiment in the present disclosure, the core insulating layer 111 may be formed of a complex polymer resin which is typically used as an interlayer insulating material. For example, the core insulating layer 111 may be formed of a pre-preg, Ajinomoto Build-up Film (ABF), or an epoxy based resin such as FR-4, Bismaleimide Triazine (BT), or the like.

According to another exemplary embodiment in the present disclosure, the first through via 121, the first circuit layer 131, and the second circuit layer 132 may be formed by a method of forming a circuit which is known in the field of circuit boards. For example, the first through via 121, the first circuit layer 131, and the second circuit layer 132 may be formed by a tenting process, a semi-additive process (SAP), or a modified semi-additive process (MSAP).

According to another exemplary embodiment in the present disclosure, the first through via 121, the first circuit layer 131, and the second circuit layer 132 may be formed of a conductive metal which is typically used in the field of circuit boards. For example, the first through via 121, the first circuit layer 131, and the second circuit layer 132 may be formed of copper.

Referring to FIG. 23, the first insulating layer 141, the second insulating layer 142, the first via 211, the second via 212, the third circuit layer 133, and the first metal layer 151 may be formed.

According to another exemplary embodiment in the present disclosure, the first insulating layer 141 may be formed on the core insulating layer 111 to embed the first circuit layer 131. In addition, the second insulating layer 142 may be formed below the core insulating layer 111 to embed the second circuit layer 132.

According to another exemplary embodiment in the present disclosure, the first insulating layer 141 and the second insulating layer 142 may be formed of a complex polymer resin which is typically used as an interlayer insulating material. For example, the first insulating layer 141 and the second insulating layer 142 may be formed of pre-preg, Ajinomoto Build-up Film (ABF), or an epoxy based resin such as FR-4, Bismaleimide Triazine (BT), or the like.

According to another exemplary embodiment in the present disclosure, the third circuit layer 133 may be formed below the second insulating layer 142. According to another exemplary embodiment in the present disclosure, the third circuit layer 133 may include the mounting pad 139. Here, the mounting pad 139 may be formed in the mounting area A and may be a circuit pattern on which external components such as an electronic element and a semiconductor package are mounted to be electrically connectable to each other.

According to another exemplary embodiment in the present disclosure, the first metal layer 151 may be formed on the first insulating layer 141.

According to another exemplary embodiment in the present disclosure, the first via 211 may penetrate through the first insulating layer 141 to electrically connect the first circuit layer 131 and the first metal layer 151 to each other. In addition, the second via 212 may penetrate through the second insulating layer 142 to electrically connect the second circuit layer 132 and the third circuit layer 133 to each other.

According to another exemplary embodiment in the present disclosure, the first via 211, the second via 212, the third circuit layer 133, and the first metal layer 151 may be formed of a conductive metal which is typically used in the field of circuit boards. For example, the first via 211, the second via 212, the third circuit layer 133, and the first metal layer 151 may be formed of copper.

According to another exemplary embodiment in the present disclosure, after the first insulating layer 141 and the second insulating layer 142 are each formed on and below the core insulating layer 111, via holes (not shown) for the first via 211 and the second via 212 may be formed. Thereafter, the first via 211, the second via 212, the third circuit layer 133, and the first metal layer 151 may be formed by using a tenting process, a semi-additive process (SAP), or a modified semi-additive process (MSAP). Here, the first metal layer 151 may be formed by a plating method, but may also be formed by a method of stacking and compressing a metal foil on the first insulating layer 141 after the first via 211 is formed.

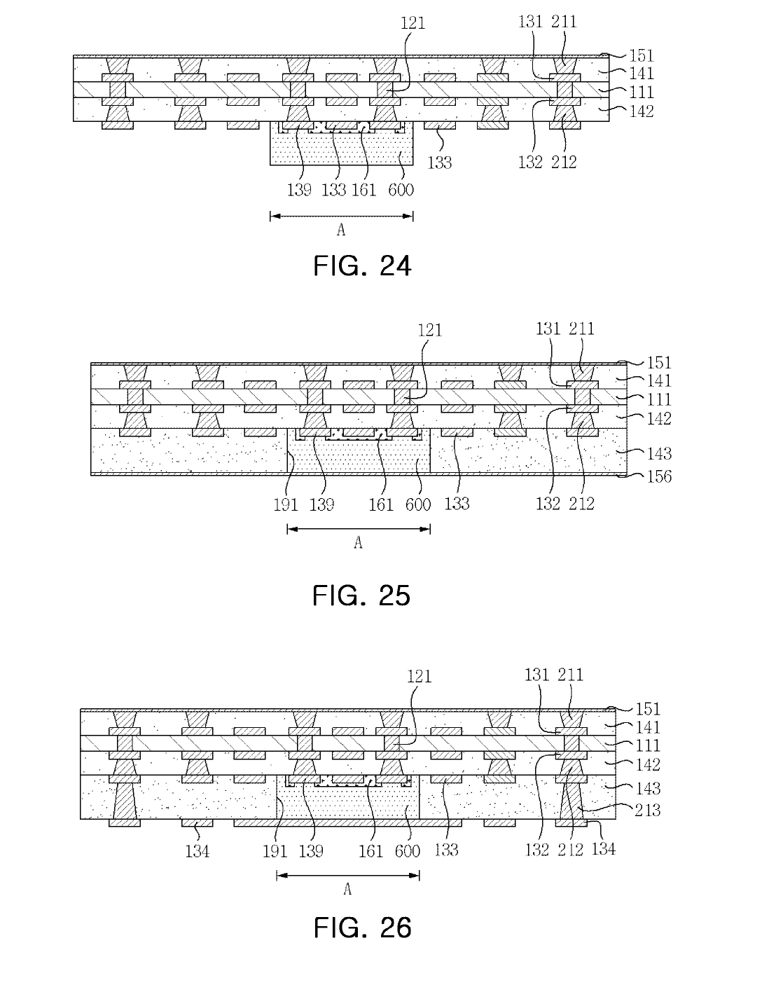

Referring to FIG. 24, the first solder resist layer 161 and the protection layer 600 may be formed below the second insulating layer 142.

According to another exemplary embodiment in the present disclosure, the first solder resist layer 161 may be formed in the mounting area A to cover and protect the third circuit layer 133. In this case, the first solder resist layer 161 may externally expose the mounting pad 139.

In addition, the protection layer 600, according to another exemplary embodiment in the present disclosure, may cover the first solder resist layer 161 and the third circuit layer 133 formed in the mounting area A. The protection layer 600 formed as described above may protect the mounting pad 139, externally exposed by the first solder resist layer 161.

The first solder resist layer 161 and the protection layer 600, according to another exemplary embodiment in the present disclosure, have been described in detail with reference to FIGS. 8 through 10.

Referring to FIG. 25, the third insulating layer 143 and the sixth metal layer 156 may be formed.

According to another exemplary embodiment in the present disclosure, the third insulating layer 143 may be formed below the second insulating layer 142 to embed the third circuit layer 133. In this case, the first cavity 191 may be formed in the third insulating layer 143, and the first cavity 191 may be formed so that the protection layer 600 is inserted into the first cavity 191.

According to another exemplary embodiment in the present disclosure, the third insulating layer 143 may be formed of a no-flow type pre-preg having low flowability of a degree that a form of the third insulating layer 143 may be maintained even though a punching process is performed. By using the pre-preg having low flowability as described above, a thickness of the third insulating layer 143 may be easily adjusted. In addition, the protection layer 600 may serve as a dam which prevents a flow of the third insulating layer 143 by a heating and compressing process. Defects caused by the third insulating layer 143 covering the mounting pad 139 may be prevented by the protection layer 600 as described above.

According to another exemplary embodiment in the present disclosure, the sixth metal layer 156 may be formed below the third insulating layer 143 and may be formed to block a lower portion of the first cavity 191. According to another exemplary embodiment in the present disclosure, the sixth metal layer 156 may be formed of a conductive metal which is used in the field of circuit boards. For example, the sixth metal layer 156 may be formed of copper.

Referring to FIG. 26, the third via 213 and the fourth circuit layer 134 may be formed.

According to another exemplary embodiment in the present disclosure, the fourth circuit layer 134 may be formed below the third insulating layer 143. In addition, the fourth via 214 may penetrate through the third insulating layer 143 to electrically connect the third circuit layer 133 and the fourth circuit layer 134 to each other.

According to another exemplary embodiment in the present disclosure, the via hole (not shown) penetrating through the third insulating layer 143 and the sixth metal layer 156 (FIG. 25) may be formed. In this case, the via hole (not shown) may be formed to externally expose a lower surface of the third circuit layer 133.

Next, the plating may be performed in the via hole (not shown) and below the sixth metal layer 156 (FIG. 25). In this case, the third via 213 may be formed in the via hole (not shown).

Next, the fourth circuit layer 134 may be formed by patterning the sixth metal layer 156 (FIG. 25) and a plated layer (not shown) formed below the sixth metal layer 156 (FIG. 25). In this case, the fourth circuit layer 134 may include a circuit pattern blocking the lower portion of the first cavity 191. As such, the circuit pattern blocking the lower portion of the first cavity 191 may prevent chemicals such as the etchant from being introduced into the first cavity 191 in subsequent processes. Therefore, chemical damage to the configuration portion exposed by the first cavity 191 may be prevented.

According to another exemplary embodiment in the present disclosure, although a case in which the third via 213 and the fourth circuit layer 134 are formed, byway of example, by the tenting process, the process of forming the third via 213 and the fourth circuit layer 134 is not limited thereto. That is, the third via 213 and the fourth circuit layer 134 may also be formed by a semi-additive process (SAP), or a modified semi-additive process (MSAP).

In addition, according to another exemplary embodiment in the present disclosure, although a case in which the third via 213 and the fourth circuit layer 134 are, by way of example, simultaneously formed has been described, the fourth circuit layer 134 may also be formed after the third via 213 is formed.

In addition, according to another exemplary embodiment in the present disclosure, the sixth metal layer 156 (FIG. 25) may be plated in order to form the fourth circuit layer. However, in a case in which the sixth metal layer 156 (FIG. 25) has a sufficient thickness as a circuit layer, the fourth circuit layer 134 may be formed by patterning the sixth metal layer 156 (FIG. 25).

According to another exemplary embodiment in the present disclosure, the third via 213 and the fourth circuit layer 134 may be formed of a conductive metal which is known in the field of circuit boards. For example, the third via 213 and the fourth circuit layer 134 may be formed of copper.

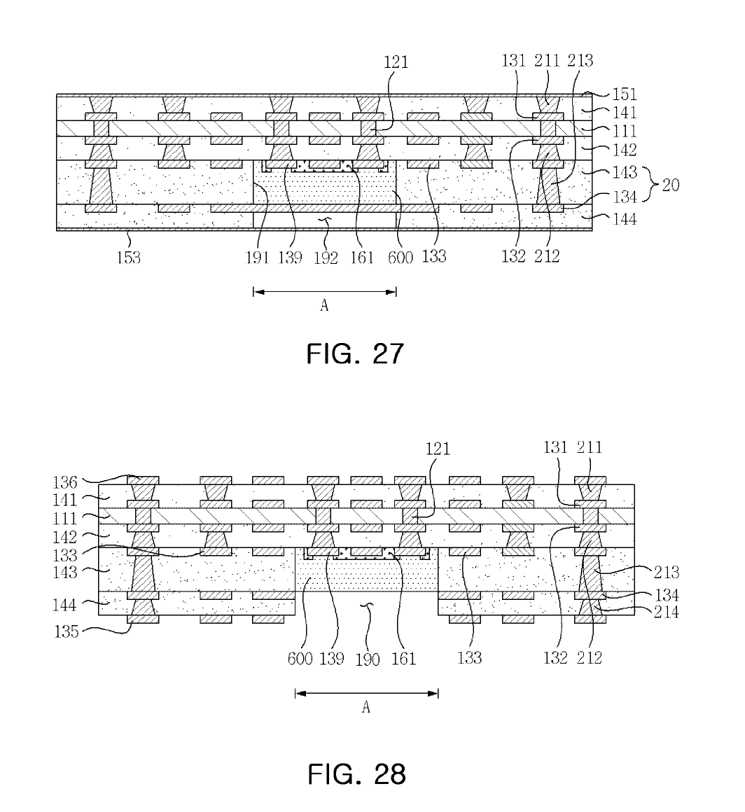

Referring to FIG. 27, the fourth insulating layer 144 and the third metal layer 153 may be formed.

A method of forming the fourth insulating layer 144 and the third metal layer 153, according to another exemplary embodiment in the present disclosure, is the same as the method of FIG. 12. Therefore, an overlapping description will be omitted, and a detailed description refers to FIG. 12.

Referring to FIG. 28, the fourth via 214, the fifth circuit layer 135, and the sixth circuit layer 136 may be formed.

According to another exemplary embodiment in the present disclosure, the fifth circuit layer 135 may be formed below the fourth insulating layer 144. In addition, the sixth circuit layer 136 may be formed on the first insulating layer 141 to be electrically connected to the first via 211. In addition, the fourth via 214 may penetrate through the fourth insulating layer 144 to electrically connect the fifth circuit layer 135 and the fourth circuit layer 134 to each other.

According to another exemplary embodiment in the present disclosure, a via hole (not shown) penetrating through the fourth insulating layer 144 and the third metal layer 153 (FIG. 27) may be formed.

Next, the plating may be performed in the via hole (not shown) and below the third metal layer 153 (FIG. 27). In this case, the plating is also performed in the via hole (not shown), such that the fourth via 214 may be formed. In addition, the plating may also be performed on the first metal layer 151 (FIG. 27).

Next, the fifth circuit layer 135 may be formed by patterning the third metal layer 153 (FIG. 27) and a plated layer (not shown) formed below the third metal layer 153 (FIG. 27). In addition, a sixth circuit layer 136 may be formed by patterning the first metal layer 151 (FIG. 27) and a plated layer (not shown) formed on the first metal layer 151 (FIG. 27).

According to another exemplary embodiment in the present disclosure, although a case in which the fourth via 214, the fifth circuit layer 135, and the sixth circuit layer 136 are, by way of example, formed by the tenting process has been described, the process of forming the fourth via 214, the fifth circuit layer 135, and the sixth circuit layer 136 is not limited thereto. That is, the fourth via 214, the fifth circuit layer 135, and the sixth circuit layer 136 may also be formed by a semi-additive process (SAP), or a modified semi-additive process (MSAP).

In addition, according to another exemplary embodiment in the present disclosure, although a case in which the fourth via 214, the fifth circuit layer 135, and the sixth circuit layer 136 are, byway of example, simultaneously formed has been described, the fifth circuit layer 135 and the sixth circuit layer 136 may also be formed after the fourth via 214 is formed.

According to another exemplary embodiment in the present disclosure, the first metal layer 151 (FIG. 27) and the third metal layer 153 (FIG. 27) may be plated in order to form the fifth circuit layer 135 and the sixth circuit layer 136. However, in a case in which the first metal layer 151 (FIG. 27) and the second metal layer 153 (FIG. 27) have sufficient thicknesses as circuit layers, the fifth circuit layer 135 and the sixth circuit layer 136 may be formed by only patterning the first metal layer 151 (FIG. 27) and the second metal layer 153 (FIG. 27). That is, the plating process is performed in the via hole (not shown), and the plating process on the first metal layer 151 and below the third metal layer 153 may be omitted.

According to another exemplary embodiment in the present disclosure, the fourth via 214, the fifth circuit layer 135, and the sixth circuit layer 136 may be formed of a conductive metal which is known in the field of circuit boards. For example, the fourth via 214, the fifth circuit layer 135, and the sixth circuit layer 136 may be formed of copper.

According to another exemplary embodiment in the present disclosure, the circuit pattern blocking the lower portions of the first cavity 191 and the second cavity 192 may also be removed when the patterning process (etching process) is performed to form the fifth circuit layer 155 and the sixth circuit layer 136. Therefore, the first cavity 191 and the second cavity 192 are connected to each other, such that one cavity 190 may be formed.

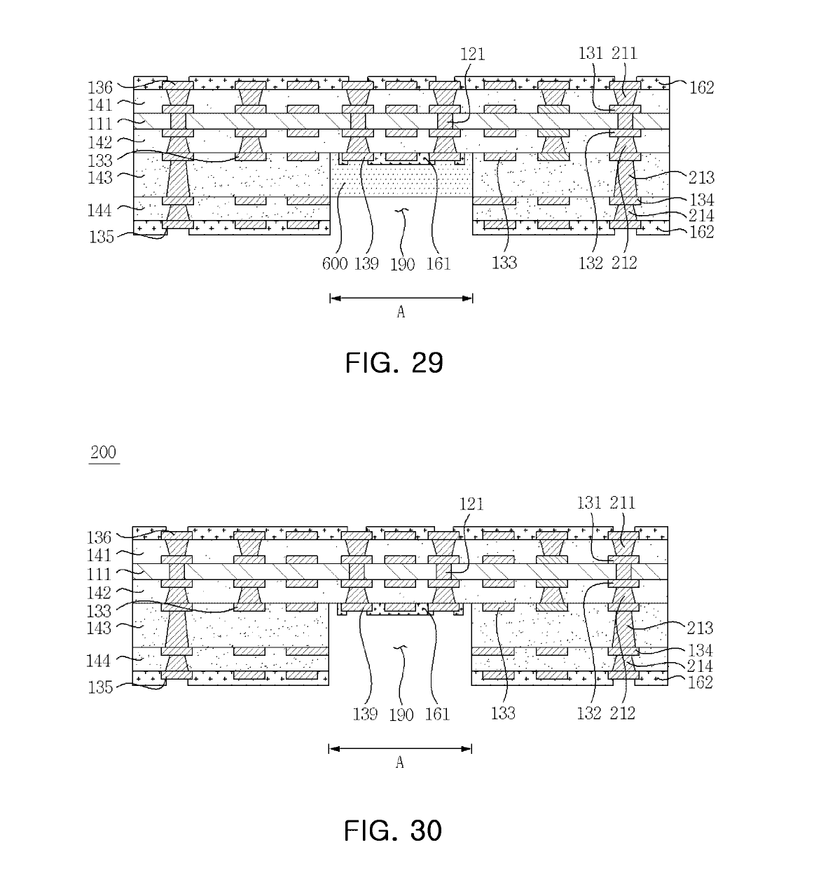

Referring to FIG. 29, the second solder resist layer 162 may be formed.

According to another exemplary embodiment in the present disclosure, the second solder resist layer 162 may be formed on the first insulating layer 141 and below the fourth insulating layer 144. The second solder resist layer 162 as described above may be formed to cover the fifth circuit layer 135 and the sixth circuit layer 136 to externally protect the fifth circuit layer 135 and the sixth circuit layer 136. In this case, the second solder resist layer 162 may be formed so that a portion which is electrically connected to the external component among the fifth circuit layer 135 and the sixth circuit layer 136 is externally exposed. According to another exemplary embodiment in the present disclosure, the second solder resist layer 162 may be formed of a heat-resistant covering material.

Referring to FIG. 30, the protection layer 600 (FIG. 29) may be removed.

According to another exemplary embodiment in the present disclosure, in a case in which the protection layer 600 (FIG. 29) is removed, the mounting pad 139 may be externally exposed.

According to another exemplary embodiment in the present disclosure, after the second solder resist layer 162 is formed, the protection layer 600 (FIG. 29) may be removed. However, the second solder resist layer 162 may also be formed after the protection layer 600 (FIG. 29) is removed.

As such, the embedded board 200 of FIG. 21 may be formed by the operations of FIGS. 22 through 30.

Although not shown in another exemplary embodiment in the present disclosure, a surface treatment layer (not shown) may be formed on the circuit pattern externally exposed among the circuit layers of the embedded board 200 according to another exemplary embodiment of FIG. 21 or 30.

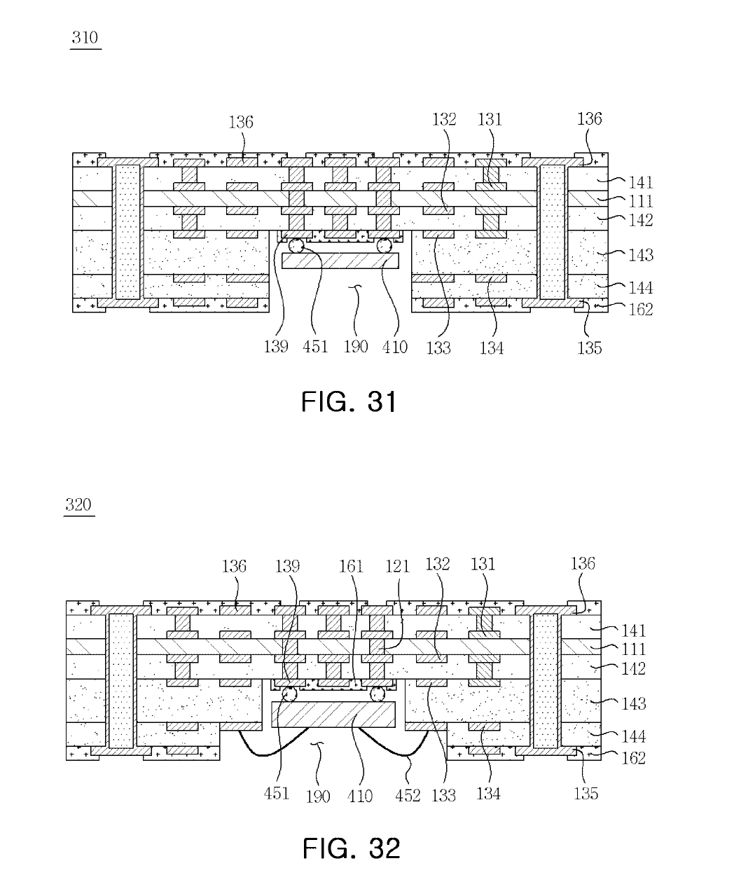

FIG. 31 is a view illustrating an embedded board on which an electronic element is disposed, according to a first exemplary embodiment in the present disclosure.

According to the first exemplary embodiment in the present disclosure, an embedded board 310 on which the electronic element is disposed may be a board to which the embedded board 100 of FIG. 1 is applied. In addition, the embedded board 200 of FIG. 21 may also be equally applied to the present exemplary embodiment. In a description of FIG. 31, a description of configurations overlapping with the embedded board 100 of FIG. 1 will be omitted.

According to the first exemplary embodiment in the present disclosure, a first electronic element 410 may be disposed in the cavity 190. In this case, the first electronic element 410 may be disposed below the mounting pad 139 to be electrically connected to the mounting pad 139 by a flip chip bonding through a solder ball 451. The third insulating layer 143 and the fourth insulating layer 144 are formed of pre-preg having low flowability, such that the cavity 190 may be easily formed. In addition, a depth of the cavity 190 may be changed by changing the thicknesses of the third insulating layer 143 and the fourth insulating layer 144. Therefore, the embedded board 310, according to the first exemplary embodiment in the present disclosure, may have the cavity 190 of which the depth may be easily adjusted depending on a thickness of the first electronic element 410.

According to the first exemplary embodiment in the present disclosure, the first electronic element 410 may also be any kind of electronic element used in the field of circuit boards which may be embedded in the board or mounted below or on the board.

Although the first exemplary embodiment in the present disclosure describes the electronic element as a configuration mounted on the embedded board 310 by way of example, the configuration mounted on the embedded board 310 is not limited thereto. For example, in the embedded board 310, a semiconductor package (not shown) instead of the first electronic element 410 may also be disposed in the cavity 190.

FIG. 32 is a view illustrating an embedded board on which an electronic element is disposed, according to a second exemplary embodiment in the present disclosure.

In an embedded board 320 according to the second exemplary embodiment in the present disclosure, the cavity 190 may be formed to have a step portion. Here, the cavity 190 may be formed to have a diameter wider in the fourth insulating layer 144 than the third insulating layer 143 to externally expose some circuit patterns of the fourth circuit layer 134.

The embedded board 320 having the structure as described above may be formed by adjusting the second cavity 192 of the fourth insulating layer 144 to have a diameter greater than that of the first cavity 191 in the operation of forming the fourth insulating layer 144 of FIG. 12. In addition, the diameter of the second cavity 192 may be formed so that a portion of the fourth circuit layer 134 is externally exposed when the fourth insulating layer 144 is stacked on the third insulating layer 143. Since the operations before and after the above-mentioned operation are the same as those of FIGS. 2 through 20, a description of a method thereof will be omitted.

The first electronic element 410 may be mounted on the mounting pad 130 of the embedded board 320 formed as described above. According to an exemplary embodiment in the present disclosure, the first electronic element 410 may also be electrically connected to the mounting pad 130 through the solder ball 451. In addition, the first electronic element 410 may be electrically connected to the fourth circuit layer 134 by a wire 452. In this case, a portion which is wire-bonded to the first electronic element 410 may be a portion of the fourth circuit layer 134 which is externally exposed by the cavity 190 having the step structure.

Although the second exemplary embodiment in the present disclosure describes a case in which the first electronic element 410 is electrically connected to the embedded board 320 by the wire 452 and the solder ball 451, one of either the wire 452 or the solder ball 451 may also be omitted.

Although the second exemplary embodiment in the present disclosure describes the electronic element as a configuration mounted on the embedded board 320 by way of example, the configuration mounted on the embedded board 320 is not limited thereto. For example, in the embedded board 320, a semiconductor package (not shown) instead of the first electronic element 410 may also be disposed in the cavity 190.

According to the second exemplary embodiment in the present disclosure, in a case in which the electronic element has a plurality of electrodes by the cavity 190 having the step structure, the electronic element may be electrically connected to the embedded board 320 through various paths.

As the embedded board 320, according to the second exemplary embodiment in the present disclosure, the embedded board in which the cavity 190 having the step structure is applied to the embedded board 100 of FIG. 1 has been described by way of example. However, the present exemplary embodiment may also be applied to an embedded board in which the cavity 190 having the step structure is applied to the embedded board 200 of FIG. 21.

FIG. 33 is a view illustrating an embedded board on which electronic elements are disposed, according to a third exemplary embodiment in the present disclosure.

According to the third exemplary embodiment in the present disclosure, the first electronic element 410 and a second electronic element 420 may be disposed on an embedded board 330.

The embedded board 330, according to the third exemplary embodiment, may have the second electronic element 420 which is further disposed on the embedded board 320 of FIG. 32.

According to the third exemplary embodiment in the present disclosure, the first electronic element 410 may be disposed below the mounting pad 139. In addition, the second electronic element 420 may be disposed below the fourth circuit layer 134. Here, the fourth circuit layer 134 on which the second electronic element 420 is disposed may be a portion which is externally exposed by the cavity 190 having the step structure.

According to the third exemplary embodiment in the present disclosure, the first electronic element 410 and the second electronic element 420 may be electrically connected to the mounting pad 139 and the fourth circuit layer 134, respectively, by the solder ball 451.

Although the third exemplary embodiment in the present disclosure describes two electronic elements as a configuration mounted on the embedded board 330 by way of example, the configuration mounted on the embedded board 330 is not limited thereto. For example, in the embedded board 330, two semiconductor packages (not shown) instead of the two electronic elements may also be disposed in the cavity 190.

According to the third exemplary embodiment in the present disclosure, even in a case in which a plurality of electronic elements are simultaneously disposed in the cavity 190 by the cavity having the step structure, the plurality of electronic elements may be electrically connected to the embedded board 330 through a simple path.

The embedded board 330, according to the third exemplary embodiment in the present disclosure, may also be an embedded board in which the cavity 190 having the step structure is applied to the embedded board 200 of FIG. 21.

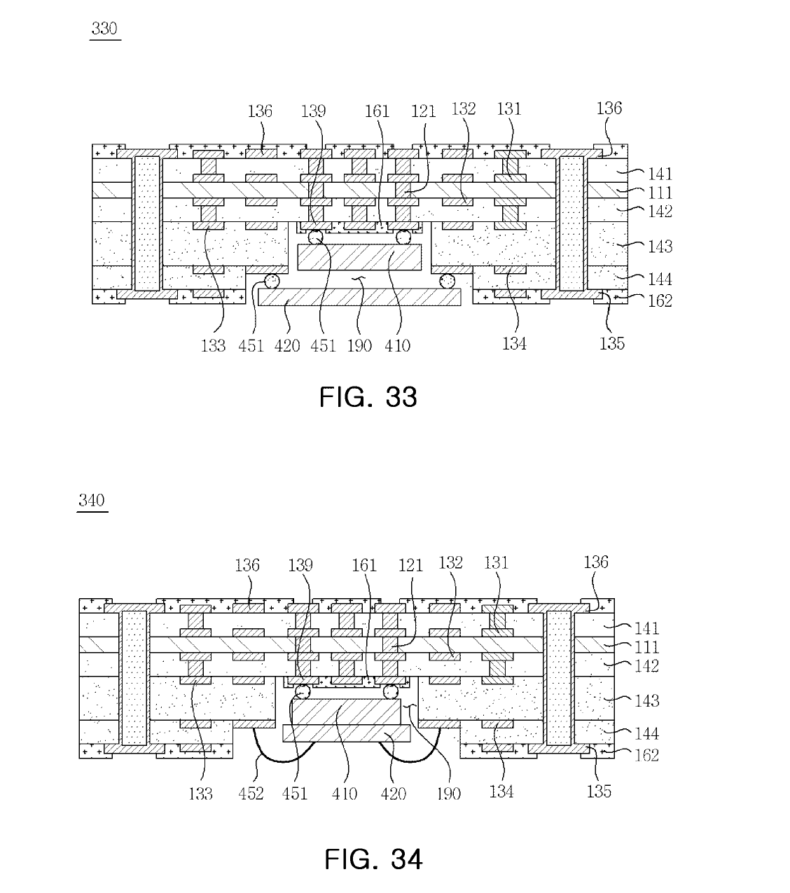

FIG. 34 is a view illustrating an embedded board on which electronic elements are disposed, according to a fourth exemplary embodiment in the present disclosure.

In an embedded board 340 according to the fourth exemplary embodiment in the present disclosure, the cavity 190 may be formed to have a step portion, and the embedded board 340 may be an embedded board to which the embedded board 320 of FIG. 32 is applied.

On the embedded board 340, according to the fourth exemplary embodiment in the present disclosure, a first electronic element 410 and a second electronic element 420 having a stacked structure may be disposed, instead of the first electronic element 410 of the embedded board 320 of FIG. 32. Here, the second electronic element 420 may be disposed below the first electronic element 410.

According to the fourth exemplary embodiment in the present disclosure, the first electronic element 410 may be electrically connected to the mounting pad by the solder ball 451. In addition, the second electronic element 420 may be electrically connected to the fourth circuit layer 134 by the wire 452.

Although the fourth exemplary embodiment in the present disclosure describes a case in which two electronic elements having a stacked structure are disposed in the embedded board 340 by way of example, the configuration disposed in the embedded board 340 is not limited thereto. For example, a multilayer semiconductor package (not shown) may also be disposed on the embedded board 340, instead of the first electronic element 410 and the second electronic element 420 having the stacked structure.

According to the fourth exemplary embodiment in the present disclosure as described above, since the embedded board 340 has the cavity 190 of which a depth is easily adjusted, the electronic element or the semiconductor package having a thick multilayer structure may be embedded in the embedded board 340 by forming the depth of the cavity 190 to be deep.

As the embedded board 340 on which the two electronic elements are disposed according to the fourth exemplary embodiment in the present disclosure, an embedded board in which the cavity 190 formed to have the step portion is formed in the embedded board 200 of FIG. 21 may be applied.

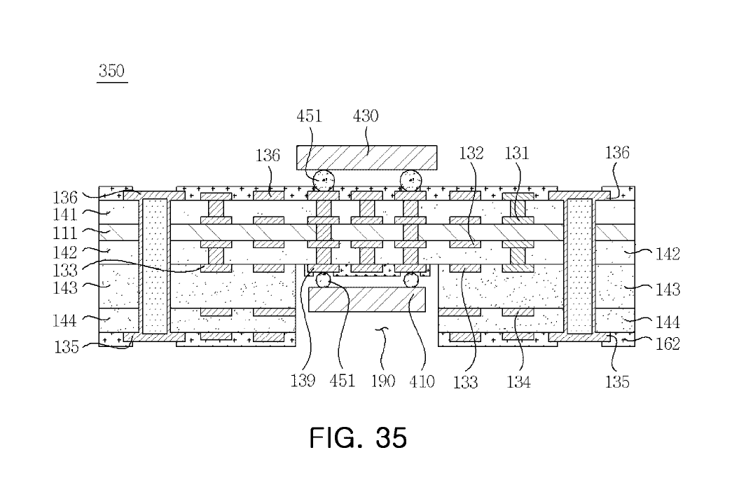

FIG. 35 is a view illustrating an embedded board on which electronic elements are disposed, according to a fifth exemplary embodiment in the present disclosure.

An embedded board 350, according to the fifth exemplary embodiment in the present disclosure, may have the first electronic element 410 embedded therein and a third electronic element 430 mounted thereon. Here, the embedded board 350 may have the third electronic element 430 which is further mounted on the embedded board 310 of FIG. 31.

According to the fifth exemplary embodiment in the present disclosure, the first electronic element 410 may be disposed in the cavity 190 of the embedded board 350. In this case, the first electronic element 410 may be electrically connected to the mounting pad 139 by the solder ball 451.

In addition, the third electronic element 430 may be mounted on the embedded board 350. In this case, the third electronic element 430 may be electrically connected to the sixth circuit layer 136 externally exposed by the second solder resist layer 162 by the solder ball 451. The third electronic element 430 may also be electrically connected to the sixth circuit layer 136 by a wire (not shown), instead of the solder ball 451.

The embedded board 350 having a structure in which the electronic elements, according to the fifth exemplary embodiment in the present disclosure, are double-sided mounted has been shown and described with reference to the embedded board 310 of FIG. 31. However, as the embedded board 350, according to the fifth exemplary embodiment, the embedded boards of FIGS. 21, and 32 to 34 may also be applied.

While exemplary embodiments have been shown and described above, it will be apparent to those skilled in the art that modifications and variations could be made without departing from the scope of the present invention as defined by the appended claims.

What is claimed is:

1. An embedded board comprising:
a core substrate below which a mounting pad is formed;
a first substrate formed below the core substrate and having a first cavity; and
a second substrate formed below the first substrate and having a second cavity,
wherein the first cavity and the second cavity are connected to each other and externally expose the mounting pad.

2. The embedded board of claim 1, further comprising a first electronic element disposed in first cavity to be electrically connected to the mounting pad.

3. The embedded board of claim 1, wherein the second cavity has a diameter greater than a diameter of the first cavity, such that a portion of a circuit layer of the first substrate is externally exposed.

4. The embedded board of claim 3, further comprising a first electronic element disposed in the first cavity to be electrically connected to the mounting pad.

5. The embedded board of claim 4, wherein the first electronic element is further electrically connected to the circuit layer of the first substrate externally exposed.

6. The embedded board of claim 4, further comprising a second electronic element disposed in the second cavity.

7. The embedded board of claim 6, wherein the second electronic element is electrically connected to the circuit layer of the first substrate externally exposed.

8. The embedded board of claim 7, wherein the second electronic element is stacked on a lower surface of the first electronic element.

9. The embedded board of claim 1, further comprising a third electronic element mounted on the core substrate.

10. A method of manufacturing an embedded board, the method comprising:
preparing a core substrate below which a mounting pad is formed;
forming a protection layer to cover the mounting pad;
forming a first substrate below the core substrate, the first substrate having a first cavity into which the protection layer is inserted;
forming a second substrate below the first substrate, the second substrate having a second cavity disposed below the first cavity; and
removing the protection layer,
wherein the first cavity and the second cavity are connected to each other and externally expose the mounting pad.

11. The method of claim 10, wherein the forming of the first substrate comprises:
forming an insulating layer of the first substrate below the core substrate, the first substrate having the first cavity into which the protection layer is inserted; and
forming a circuit layer of the first substrate on a lower surface of the insulating layer, the circuit layer of the first substrate comprising a circuit pattern formed to block a lower portion of the first cavity.

12. The method of claim 11, wherein the forming of the second substrate includes:
forming an insulating layer of the second substrate below the first substrate, the second cavity disposed below the first cavity being formed in the second substrate;
forming a metal layer formed on a lower surface of the insulating layer of the second substrate to block a lower portion of the second cavity; and
forming a circuit layer of the second substrate by patterning the metal layer,
wherein when the circuit layer of the second substrate is formed, the circuit pattern formed at the lower portion of the first cavity and the metal layer formed at the lower portion of the second cavity are removed.

13. The method of claim 10, further comprising: after the removing of the protection layer, electrically connecting a first electronic element to the mounting pad by disposing the first electronic element in the first cavity and the second cavity.

14. The method of claim 10, wherein in the forming of the second substrate, the second cavity has a diameter greater than a diameter of the first cavity to externally expose a portion of a circuit layer of the first substrate.

15. The method of claim 14, further comprising: after the removing of the protection layer, electrically connecting a first electronic element to the mounting pad by disposing the first electronic element in the first cavity.

16. The method of claim 15, wherein the electrically connecting of the first electronic element to the mounting pad further comprises electrically connecting the first electronic element to the circuit layer of the first substrate externally exposed.

17. The method of claim 15, further comprising: after electrically connecting the first electronic element to the mounting pad, electrically connecting a second electronic element to a circuit layer of the second substrate externally exposed, by disposing the second electronic element in the second cavity.

18. The method of claim 17, wherein the second electronic element is stacked on a lower surface of the first electronic element.

19. The method of claim 10, wherein in the forming of the protection layer, the protection layer is formed to have substantially the same thickness as a depth of the first cavity.

20. The method of claim 10, further comprising: after the forming of the protection layer, mounting a third electronic element on the core substrate.
